(19) United States
(12) Patent Application Publication
(10) Pub. No.: US 2013/0213700 A1
(43) Pub. Date: Aug. 22, 2013

(54) MANUFACTURING METHOD OF ELECTRODE SUBSTRATE

(71) Applicants: Ye Seul Kim, Incheon (KR); Jeong Han Kim, Seongnam-si (KR); Ji Sung Kim, Seoul (KR); Ki Nam Kwak, Yongin-si (KR)

(72) Inventors: Ye Seul Kim, Incheon (KR); Jeong Han Kim, Seongnam-si (KR); Ji Sung Kim, Seoul (KR); Ki Nam Kwak, Yongin-si (KR)

(73) Assignee: KOLON INDUSTRIES, INC., Gwacheon-si, Gyeonggi-do (KR)

(21) Appl. No.: 13/877,040

(22) PCT Filed: Sep. 28, 2011
(86) PCT No.: PCT/KR11/07154

§ 371 Date: Apr. 30, 2013

(30) Foreign Application Priority Data
Sep. 30, 2010 (KR) 10-2010-0095674

(51) Int. Cl. H05K 3/00; H05K 1/09

(52) U.S. Cl. CPC H05K 3/00; H05K 1/097
USPC 174/255; 427/58

(57) ABSTRACT

Provided is a manufacturing method of an electrode substrate in which a carbon nanotube is strongly bonded on a base by forming a mixed film of the carbon nanotube and a silicon-based organic and inorganic hybrid polymer.

### TECHNICAL FIELD

The present invention relates to a manufacturing method of an electrode substrate and more particularly, to a manufacturing method of an electrode substrate including a carbon nanotube layer on a film surface of a polymer resin material.

### BACKGROUND ART

As computers, various electric appliances and communication equipments are digitized and rapidly have high performance, implementation of large-screen and potable displays is acutely required. In order to implement portable, large-screen, and flexible displays, display materials of folding or rolling materials like a newspaper are required.

For this, an electrode material for a display is transparent and has a low resistance value, has high strength so as to be mechanically stabilized even when bending or folding the element, and has a thermal expansion coefficient similar to a thermal expansion coefficient of a plastic substrate such that the equipment is not overheated or short-circuited or has small surface resistance even at a high temperature.

Since the flexible display enable the manufacture of the display having any form, the flexible display may be used even for a portable display device, clothes capable of changing colors and patterns, trademark of clothes, billboards, price signs of display stalls, large-area electric illuminations, and the like.

In this connection, a transparent conductive thin film is a material widely used to devices such as an image sensor, a solar cell, various displays (PDP, LCD, and flexible), and the like for both transmission of light and conductivity.

In general, indium tin oxide (ITO) has been largely developed as the transparent electrode for a flexible display, but in order to manufacture an ITO thin film, basically, a process in a vacuum state is required, such that a high-price processing cost is required and a lifespan is shortened due to break of the thin film when the flexible display element is bent or folded.

In order to solve the problem, disclosed was a transparent electrode having transmittance of 80% or more in a visible light area and the surface resistance of 100 Ω/sq or less capable of minimizing scattering of light and improving conductivity in the visible light area, in which a carbon nanotube is dispersed at the inside or on the surface of a coating layer by a nanoscale and metallic nanoparticles such as gold, silver, and the like are mixed therein by molding the carbon nanotube to a film after chemically bonding the carbon nanotube with a polymer or coating the refined carbon nanotube or the carbon nanotube bonded with the polymer on a conductive polymer layer (KR-A-10-2005-001589). In detail, a high-concentration of carbon nanotube polymer copolymer solution is prepared by reacting with a carbon nanotube dispersion solution and polyethyleneterephthalate and then, is applied on a polyester film substrate and dried, thereby manufacturing the transparent electrode.

A separate substrate is required in the manufacture of the film substrate using the carbon nanotube and a PET substrate has almost been used as an example of the transparent substrate.

### DISCLOSURE OF INVENTION

### Technical Problem

Meanwhile, in the related art, it was difficult to disperse uniformly the carbon nanotube in order to forming a carbon nanotube layer and it was difficult to ensure substrate adhesion between the carbon nanotube layer and the substrate layer.

### Solution to Problem

The present invention has been made in an effort to provide a method of manufacturing an electrode substrate by forming a mixed film capable of strongly boning a carbon nanotube on a base without using additional additives such as a dispersant, a binder, and the like when a carbon nanotube layer of the electrode substrate is formed.

An exemplary embodiment of the present invention provides a manufacturing method of an electrode substrate including: forming a carbon nanotube dispersing layer by coating a carbon nanotube dispersion solution including a dispersant on a polymer substrate; removing the dispersant from the carbon nanotube dispersing layer; and forming a mixed film of the carbon nanotube and a silicon-based organic and inorganic hybrid polymer by using a silicon-based organic and inorganic hybrid polymer solution on the polymer substrate in which the carbon nanotube dispersing layer without the dispersant is included.

The dispersant may be one or more selected from sodium dodecyl sulfate, lithium dodecyl sulfate, sodium dodecyl benzenesulfonate, sodium dodecylsulfonate, dodecyltrimethylammonium bromide, cetyltrimethylammonium bromide.

The carbon nanotube may be selected from a single-wall carbon nanotube, a double-wall carbon nanotube, and a multi-wall carbon nanotube.

The substrate may be manufactured by including one or more polymer selected from polyamide, polyethersulfone, polyetheretherketone, polyethylene terephthalate, polybutylene terephthalate, polycarbonate, polyacrylate, and polyurethane.

The silicon-based organic and inorganic hybrid polymer may be one or more selected form a group configured by polycarbosilane, polysilane, polysiloxane, polysilazane polymers and a derivatives of the polymers.

The forming of the mixed film of the carbon nanotube and a silicon-based organic and inorganic hybrid polymer may include coating the silicon-based organic and inorganic hybrid polymer solution on the substrate in which the carbon nanotube dispersing layer without the dispersant is included; drying the coated substrate; and curing the coated substrate.

The forming of the mixed film of the carbon nanotube and a silicon-based organic and inorganic hybrid polymer may include immersing the substrate in which the carbon nanotube dispersing layer without the dispersant is included in the polymer solution; drying the immersed substrate; and curing the immersed substrate.

A thickness of the mixed film of the carbon nanotube and a silicon-based organic and inorganic hybrid polymer may be 0.001 to 0.1 μm.

Another exemplary embodiment of the present invention provides an electrode substrate acquired by the manufacturing method and including a polymer resin base in which the mixed film of the carbon nanotube and a silicon-based organic and inorganic hybrid polymer without the dispersant is formed on the surface.

### BEST MODE FOR CARRYING OUT THE INVENTION

Hereinafter, the present invention will be described below in more detail.

A method of preparing a carbon nanotube dispersion solution is not particularly limited, but the carbon nanotube dispersion solution may be prepared by mixing the carbon nanotube in a dispersant aqueous solution, dispersing the carbon nanotube by using a sonicator, and separating the agglomerate carbon nanotube from the dispersion solution by using a centrifuge.

In this case, the dispersant may be an anion surfactant such as sodium dodecyl sulfate, lithium dodecyl sulfate, sodium dodecylbenzene sulfonate, sodium dodecylsulfonate, and the like and a cation surfactant such as dodecyl trimethyl ammonium bromide, cetyltrimethyl ammonium bromide, and the like.

The carbon nanotube is not particularly limited and may be a single-wall carbon nanotube, a double-wall carbon nanotube, a multi-wall carbon nanotube, or the like.

Water may be used as a solvent dispersing the carbon nanotube and the dispersant.

The content of the carbon nanotube in the acquired carbon nanotube dispersion solution is 0.0001 to 0.2 wt %, which is preferable in view of transmittance of the electrode base after coating.

The acquired carbon nanotube dispersion solution is spray-coated on the substrate while heating the substrate at a temperature of 80° C. or more and then, the substrate coated with the carbon nanotube is immersed in water for 10 minutes or more to remove the dispersant.

A carbon nanotube dispersing layer is formed on the substrate by the above method to remove the dispersant and then, a silicon-based organic and inorganic hybrid polymer solution is introduced thereinto by bar coating, slit coating, spray coating, spin coating, embedding methods.

The polymer resin material substrate may be selected from a heat ?resistant polymer such as a polyimide resin, polyethersulfone, polyetheretherketone, and the like or a polymer resin material substrate such as polyethylene terephthalate, polybutylene terephthalate, polycarbonate, polyacrylate, polyurethane, and the like.

The silicon-based organic and inorganic hybrid polymer may be a polymer such as polycabosilane, polysilane, polysiloxane, polysilazane, and the like and a derivative of the polymer and a substituent of each polymer may be substituted by a hydrogen atom, or an alkyl group, an alkenyl group, a cycloalkyl group, an aryl group, an alkyl silyl group, alkoxy group, or the like.

The solvent of the silicon-based organic and inorganic hybrid polymer is preferably one or more selected from a group configured by acetone, tetrahydrofuran, dioxane, methylene chloride, chloroform, cyclohexane, cyclohexanone, methylethylketone, n-Hexane, diethylether, dibutylether, ethylacetate and may be a mixture thereof. Any solvent capable of dissolving the silicon-based organic and inorganic hybrid polymer may also be used such that it is not limited thereto.

The concentration of the silicon-based organic and inorganic hybrid polymer solution may be 0.01 to 10 wt %. When the polymer solution is coated in the concentration range, a mixed film of the carbon nanotube and the silicon-based organic and inorganic hybrid polymer. In the case where the concentration range is diverged, the formed mixed film of the carbon nanotube and the silicon-based organic and inorganic hybrid polymer may have a limit to characteristics of surface resistance, adhesion, and the like.

The substrate where the carbon nanotube dispersing layer without the dispersant is included is immersed in the silicon-based organic and inorganic hybrid polymer solution or the substrate is coated with the silicon-based organic and inorganic hybrid polymer solution and thereafter, the mixed film of the carbon nanotube and the silicon-based organic and inorganic hybrid polymer may be formed through drying and curing.

In particular, the drying may be performed by drying the mixed film of the carbon nanotube and the silicon-based organic and inorganic hybrid polymer which is formed in the polymer substrate at 80° C. to 400° C. for 3 minutes or more. When the temperature and the time are out of the range, the remaining solvent in the film which is not dried acts as a disturbing factor in a subsequent curing process such that the mixed film of the carbon nanotube and the silicon-based organic and inorganic hybrid polymer is not uniformly formed to cause a problem on a characteristic of the final mixed film.

The curing may be performed by exposing the mixed film at UV rays of 100 mJ to 1000 mJ if necessary, under the temperature of 80° C. to 150° C. and the humidity of 80 RH % to 95 RH %. The silicon-based organic and inorganic hybrid polymer is cured even out of the temperature and humidity range such that the mixed film of the carbon nanotube and the silicon-based organic and inorganic hybrid polymer may be formed, but considering a curing speed and particularly, a density of the formed film, the curing in the range is judged as an optimal condition up to now. The curing using the UV rays may control exposure strength by controlling an exposure time and it is not limited to the condition.

Meanwhile, the process of forming the mixed film of the carbon nanotube and the silicon-based organic and inorganic hybrid polymer may be performed so as to have a thickness of 0.001 to 0.1 μm of the polymer mixed film. When the thickness of the mixed film of the carbon nanotube and the silicon-based organic and inorganic hybrid polymer is less than 0.001 μm, the adhesion due to the silicon-based organic and inorganic hybrid polymer is deteriorated and when the thickness is more than 0.1 μm, the surface resistance characteristic, the transmittance, and a flexible characteristic may be hindered.

As described above, since the silicon-based organic and inorganic hybrid polymer solution introduced in the substrate is substantially separated from the carbon nanotube dispersing layer, the silicon-based organic and inorganic hybrid polymer solution which is coated or immersed is bonded to the carbon nanotube of the carbon nanotube dispersing layer rather than formation of the layer, such that the mixed film of the carbon nanotube and the silicon-based organic and inorganic hybrid polymer is formed so as to maintain a strong bond.

As described above, the product acquired by an exemplary embodiment is configured by the polymer resin base including the mixed film of the carbon nanotube and the silicon-based organic and inorganic hybrid polymer without the dispersant on the surface, which is useful for the electrode substrate requiring the high strength due to the strong bond of the polymer mixed film.

### MODE FOR THE INVENTION

Hereinafter, the present disclosure will be described in detail based on Examples, but the present disclosure is not limited to Examples.

### EXAMPLE 1

The carbon nanotube (single-wall carbon nanotube, product of Nanosolution Co., Ltd.) was mixed in an aqueous solution of sodium dodecyl sulfate of 1 wt % by a concentration of 1 mg/ml and then, dispersed by using a sonicator for 1 hour. The agglomerate carbon nanotube was separated by the dispersion solution by using the centrifuge to acquire the carbon nanotube dispersion solution having an excellent degree of dispersion.

The acquired carbon nanotube dispersion solution was sprayed on the surface of a polyethyleneterephthalate (PET) substrate and dried at 80° C. In order to remove sodium dodecyl sulfate included in the carbon nanotube dispersing layer, the carbon nanotube dispersion solution was sufficiently cleaned with distilled water.

Thereafter, a hybrid solution of polysilazan and methylethylketone in which the solid content was 5 wt % was bar-coated on the polymer substrate coated with carbon nanotube.

Thereafter, the polymer resin film was formed by drying at 120° C. for 1 hour and then, curing at 80° C. and 95 RH % for 3 hours, thereby acquiring the carbon nanotube layer without the dispersant on the surface.

### EXAMPLE 2

The electrode substrate was manufactured by the same as Example 1, but the hybrid solution of polysilazan and methylethylketone was spray-coated on the polymer substrate coated with carbon nanotube.

### EXAMPLE 3

The electrode substrate was manufactured by the same as Example 1, but the hybrid solution of polysilazan and methylethylketone was spin-coated on the polymer substrate coated with carbon nanotube.

### EXAMPLE 4

The electrode substrate was manufactured by the same as Example 1, but the sodium dodecyl benzenesulfonate instead of sodium dodecyl sulfate was used in preparing of the carbon nanotube dispersion solution.

### EXAMPLE 5

The electrode substrate was manufactured by the same as Example 1, but a polysilazan polymer solution of 0.1 wt % was used.

### EXAMPLE 6

The electrode substrate was manufactured by the same as Example 1, but the polymer substrate coated with carbon nanotube was immersed in the polymer solution for immersion for 10 minutes.

### COMPARATIVE EXAMPLE 1

The electrode substrate was manufactured by the same as Example 1, but the process of introducing the silicon-based organic and inorganic hybrid polymer was omitted.

Evaluation for physical properties was performed as follows with respect to the electrode substrate acquired form Examples 1 to 6 and Comparative Example 1. The result thereof was shown in Table 1.

(1) Optical Property

Visible-ray transmittance was measured by using UV spectrometer (Varian Co., Ltd., Cary 100) with respect to the manufactured transparent electrode film.

(2) Surface Resistance

The surface resistance was measured ten times by using a high resistance meter (Hiresta-UP MCT-HT450 of Mitsubishi Chemical Corporation) (measurement range: 10×10⁵˜10×10¹⁵) and a low resistance meter (CMT-SR 2000N of Advanced Instrument Technology (AIT) Co., Ltd., 4-Point Probe System) (measurement range: 10×10⁻³˜10×10⁵) to calculate average thereof.

(3) Evaluation for Adhesion

Adhesion between the carbon nanotube layer and the polymer substrate layer was measured through a tape method (ASTM D 3359-02) and evaluated. The carbon nanotube coated substrate was divided into 25 spaces by using a knife (5×5) and then, the tape was attached without air and the tape was detached at a time. Thereafter, the surface resistance was measured in each area. When the area where the change of the surface resistance was observed was 0%, the adhesion was represented by 5B, 5% or less represented by 4B, 5 to 15% represented by 3B, 15 to 35% represented by 2B, 35 to 65% represented by 1B, and 65% or more represented by 0B.

TABLE 1

| | | | Surface | | Surface | |
|---|---|---|---|---|---|---|
| | Total | Transmittance | resistance | Transmittance | resistance | |
| | thickness | before coating | before coating | after coating | before coating | Adhesion |
| | (μm) | (550 nm, %) | (Ω/Sq) | (550 nm, %) | (Ω/Sq) | test |
| Example 1 | 0.1 | 87.2 | 270 | 87.3 | 326 | 5B |
| Example 2 | 0.1 | 87.9 | 320 | 88 | 375 | 5B |
| Example 3 | 0.1 | 87.1 | 259 | 87 | 305 | 5B |
| Example 4 | 0.1 | 87.6 | 294 | 87.6 | 343 | 5B |
| Example 5 | 0.1 | 87.3 | 279 | 87.3 | 301 | 5B |
| Example 6 | 0.1 | 88.0 | 330 | 87.4 | 413 | 5B |
| Comparative | 0.1 | 88.2 | 356 | — | — | 4B |
| Example 1 | | | | | | |

From the result of Table 1, the prepared transparent electrode film formed the mixed film of the carbon nanotube and the silicon-based organic and inorganic hybrid polymer by introducing the silicon-based organic and inorganic hybrid polymer to the carbon nanotube layer, such that the carbon nanotube layer was firmly adhered to the substrate layer. Further, the silicon-based organic and inorganic hybrid polymer did not affect the transmittance and the surface resistance of the transparent electrode film and caused a difference in increase degree of the surface resistance.

Simple modifications and changes and modifications of the present invention can be easily made by those skilled in the art and it can be understood that these modifications and changes are included in the scope of the present invention.

1. A manufacturing method of an electrode substrate, comprising:
forming a carbon nanotube dispersing layer by coating a carbon nanotube dispersion solution including a dispersant on a polymer substrate;
removing the dispersant from the carbon nanotube dispersing layer; and
forming a mixed film of the carbon nanotube and a silicon-based organic and inorganic hybrid polymer by using a silicon-based organic and inorganic hybrid polymer solution on the polymer substrate in which the carbon nanotube dispersing layer without the dispersant is included.

2. The manufacturing method of an electrode substrate of claim 1, wherein the dispersant is one or more selected from the group consisting of sodium dodecyl sulfate, lithium dodecyl sulfate, sodium dodecyl benzenesulfonate, sodium dodecylsulfonate, dodecyltrimethylammonium bromide, cetyltrimethylammonium bromide.

3. The manufacturing method of an electrode substrate of claim 1, wherein the carbon nanotube is selected from the group consisting of a single-wall carbon nanotube, a double-wall carbon nanotube, and a multi-wall carbon nanotube.

4. The manufacturing method of an electrode substrate of claim 1, wherein the substrate is manufactured by including one or more polymer selected from the group consisting of polyamide, polyethersulfone, polyetheretherketone, polyethylene terephthalate, polybutylene terephthalate, polycarbonate, polyacrylate, and polyurethane.

5. The manufacturing method of an electrode substrate of claim 1, wherein the silicon-based organic and inorganic hybrid polymer is one or more selected the group consisting of polycarbosilane, polysilane, polysiloxane, polysilazane polymers and a derivatives of the polymers.

6. The manufacturing method of an electrode substrate of claim 1, wherein the forming of the mixed film of the carbon nanotube and a silicon-based organic and inorganic hybrid polymer includes
coating the silicon-based organic and inorganic hybrid polymer solution on the substrate in which the carbon nanotube dispersing layer without the dispersant is included;
drying the coated substrate; and
curing the coated substrate.

7. The manufacturing method of an electrode substrate of claim 1, wherein the forming of the mixed film of the carbon nanotube and a silicon-based organic and inorganic hybrid polymer includes
immersing the substrate in which the carbon nanotube dispersing layer without the dispersant is included in the polymer solution;
drying the immersed substrate; and
curing the immersed substrate.

8. The manufacturing method of an electrode substrate of claim 6, wherein the drying is performed at 80 to 400° C. for 3 min or more and the curing is performed under 80 to 150° C. and 80 RH % to 95 RH %.

9. The manufacturing method of an electrode substrate of claim 1, wherein a thickness of the mixed film of the carbon nanotube and a silicon-based organic and inorganic hybrid polymer is 0.001 to 0.1 μm.

10. An electrode substrate prepared by the manufacturing method of claim 1 and comprising a polymer resin base in which the mixed film of the carbon nanotube and a silicon-based organic and inorganic hybrid polymer without the dispersant is formed on the surface.

11. The manufacturing method of an electrode substrate of claim 7, wherein the drying is performed at 80 to 400° C. for 3 min or more and the curing is performed under 80 to 150° C. and 80 RH % to 95 RH %.
